(19) United States
(12) Patent Application Publication
(10) Pub. No.: US 2004/0137371 A1
(43) Pub. Date: Jul. 15, 2004

(54) Method of making a semiconductor device using a pellicle that is transparent at short wavelengths

(76) Inventors: Cesar M. Garza, Round Rock, TX (US); Thomas Ray Bierschenk, Georgetown, TX (US); Han-Chao Wei, Austin, TX (US); Hajimu Kawa, Austin, TX (US)

Correspondence Address: FREESCALE SEMICONDUCTOR, INC., LAW DEPARTMENT, 7700 WEST PARMER LANE MD:TX32/PL02, AUSTIN, TX, 78729, US

(21) Appl. No.: 10/339,062

(22) Filed: Jan. 9, 2003

(51) Int. Cl. G03F 7/20

(52) U.S. Cl. 430/311; 430/327; 430/5

(57) ABSTRACT

In semiconductor manufacturing, a pellicle film (28) is used to protect the surface of a reticle (24). The reticle (24) is used in an optical microlithography system (10) to pattern semiconductor wafers (18). To work properly, the pellicle (28) must be transparent at the particular wavelength of light used to expose photoresist through the reticle (24). The pellicle (28) is made more transparent to short wavelength light used by the optical microlithography system by removing unwanted hydrogen in the pellicle (28). The unwanted hydrogen is removed by exposing the pellicle (28) to a gas containing fluorine. This unwanted hydrogen apparently came as artifacts of the process of the making the pellicle (28), particularly the chemicals introduced to terminate the polymerization process and the ones used as solvents.

### FIELD OF THE INVENTION

This invention relates to semiconductor devices, and more particularly to making a pellicle used in the manufacture semiconductor devices.

### BACKGROUND OF THE INVENTION

Optical microlithography is used in the manufacture of semiconductor devices. An optical microlithography system comprises four basic elements: an illumination system, a reticle, an exposure system, and a wafer. The reticle, also known as a photomask or mask, consists of a pattern of transparent and opaque areas in a transparent substrate. These opaque and transparent areas comprise the master pattern that will be replicated over and over again by the exposure system, using the illumination system as the light, or radiation source, onto to the wafer surface that has been coated with a photosensitive material known as photoresist. In practice, the illumination and exposure system are contained in the same piece of equipment commonly known as a stepper or a scanner.

Because of the very small feature sizes involved in semiconductor processing, a small contaminant (for example, a speck of dust) may result in a distorted pattern that will prevent the semiconductor device from working as intended, or even not working at all. To avoid this problem, a protective cover is used over the reticle. This protective cover is a thin, free-standing film known as a “pellicle”. Ideally, the pellicle will transmit all or most of the light from the illumination system and does not degrade over time. The pellicle is attached to a frame, which in turn is attached to the reticle. In this arrangement, the pellicle is at a certain distance away from the reticle so that a particle or piece of dust on the pellicle will be out of focus and will not distort the master pattern on the reticle.

Optical microlithography systems typically operate in a diffraction-limited mode, meaning the smallest features they can replicate on the wafer are limited by the diffraction of the light as it goes through the master pattern on the reticle. To alleviate this problem, shorter and shorter wavelengths are used in the illumination system. The first illumination wavelength to gain wide acceptance was 436 nm (nanometers), followed by 365 nm, followed by 248 nm. Presently, state-of-the-art scanners use 193 nm radiation. The semiconductor industry is currently contemplating reducing the illumination wavelength to 157 nm. One problem with this is that known pellicle materials become opaque to the light at decreasing wavelengths. Thus, pellicle materials suitable at one wavelength absorb too much of the illumination or degrade too quickly at a shorter wavelength.

Therefore, there is a need for a pellicle that will be suitable for use at even shorter wavelengths to keep pace with state-of-the-art scanners.

### BRIEF DESCRIPTION OF THE DRAWINGS

FIG. 1 illustrates an optical microlithography system in accordance with the present invention.

FIG. 2 illustrates, in flow chart form, a method for making a semiconductor device in accordance with the present invention.

### DETAILED DESCRIPTION OF THE PREFERRED EMBODIMENT

Generally, the present invention provides a pellicle for use in an optical microlithography system that is substantially transparent to light having a wavelength of 157 nm. The pellicle is made from a copolymer of fluorocarbons, such as for example Teflon® AF available from DuPont. The pellicle film is mounted to a pellicle frame and then placed in a fluorine gas environment. The fluorine atoms replace unwanted hydrogen atoms present in the copolymer as well as remove unwanted carboxylic acid end-groups. Replacing the unwanted hydrogen atoms and carboxylic acid end-groups with fluorine atoms improves the ability of the pellicle to transmit light having a wavelength of 157 nm.

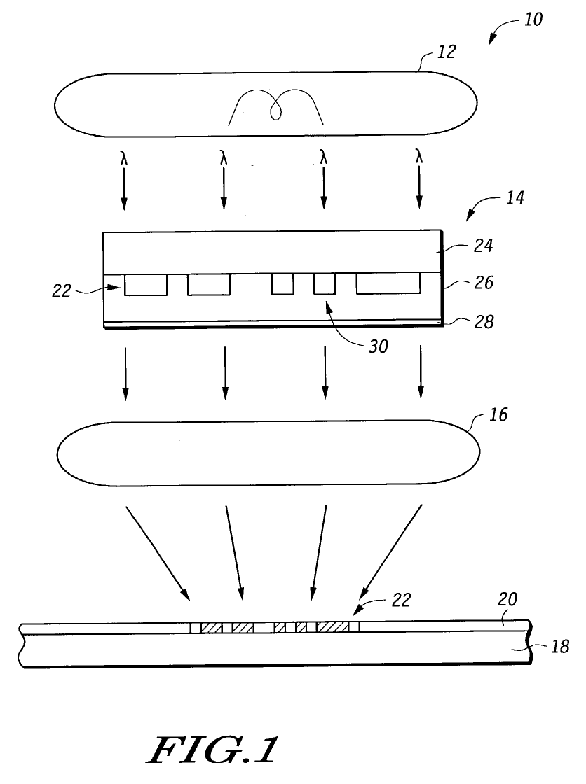

FIG. 1 illustrates an optical microlithography system 10 in accordance with the present invention. Optical microlithography system 10 includes an illumination system 12, a reticle system 14, an exposure system 16, and a semiconductor wafer 18 to be processed. Illumination system 12 provides the light source and associated optical elements. In the illustrated embodiment, illumination system 12 includes a fluorine excimer laser to provide illumination at a wavelength of 157 nm (nanometers). Reticle system 14 is illustrated in cross-section and includes a reticle 24, a pellicle frame 26, and a pellicle film 28. Reticle 24, also known as a photomask or mask, has a surface that comprises transparent and opaque areas in a transparent substrate 22. The opaque and transparent areas comprise the pattern of electrical circuits, for example, that will be replicated onto the surface of the semiconductor wafer 18 via exposure system 16.

Pellicle film 28 is positioned on frame 26. Frame 26 is mounted onto a surface of reticle 24 and holds pellicle film 28 a predetermined distance from the reticle surface. In one embodiment, the predetermined distance is about 5 millimeters (mm). The surface of wafer 18 is coated with a photosensitive material 20 known as photoresist. Lithography system 10 is used to expose portions of photoresist 20 using the patterns printed on the reticle 24. Generally, the patterns on reticle 24 are several times larger than the resulting patterns on wafer 18. Many reticles having different patterns are used in a determined sequence to process one semiconductor wafer 18. In practice, the illumination and exposure system are contained in the same piece of equipment which is commonly known as a stepper or a scanner.

In the past, the material of choice for making pellicles that transmit light at a wavelength of 436 nm and 365 nm was nitrocellulose. However, nitrocellulose becomes too absorptive at wavelengths of 365 nm and 248 nm and it was replaced by fluorocarbons related to Teflon® and Cytop™. Cytop™ is available through Asahi Glass Company. (Note that Teflon® is a registered trademark of Dupont and Cytop™ is a trademark of Asahi Glass Company). Teflon® AF is a copolymer of tetrafluoroethylene and 2,2-bis(trifluoromethyl)-4,5-difluoro-1,3-dioxole. However, it has been found that Teflon® AF absorbs too much light at the 157 nm wavelength. The presence of unwanted hydrogen atoms in Teflon® AF is believed to result in the lower 157 nm wavelength light transmission. Also, any hydrogen atoms present in the polymer may accelerate the decomposition of the polymer during use. The unwanted hydrogen atoms may be in the Teflon® AF due to residual organic solvent used to make the pellicle. Also, the unwanted hydrogen may result from carboxylic acid end-groups on the capping moieties. In addition, the unwanted hydrogen may be a part of the copolymer structure itself.

A pellicle film is made by first dissolving a suitable polymer like Teflon® AF in a solvent. The solution is then spin-coated onto a glass substrate. The substrate is heated to drive the solvent off, and the resulting film is lifted from the glass, stretched tightly, and attached to a pellicle frame.

The pellicle film is a solid that comprises polymer chains with capping chemical moieties at both ends, residual solvents and other impurities including hydrogen bonded to the polymer. The unwanted hydrogen is removed from the pellicle film by replacing the hydrogen atoms with fluorine atoms. The unwanted carboxylic acid end-group moieties are replaced by more stable trifluoromethyl end-groups upon exposure to fluorine gas. By replacing the hydrogen with fluorine and by removing the carboxylic acid moieties, pellicle film 28 is relatively more transparent to light having a wavelength of 157 nm. Also, pellicle film 28 has lower water absorption, lower surface energy to reduce particulate adhesion, and better chemical resistance than a pellicle film that has not been exposed to fluorine.

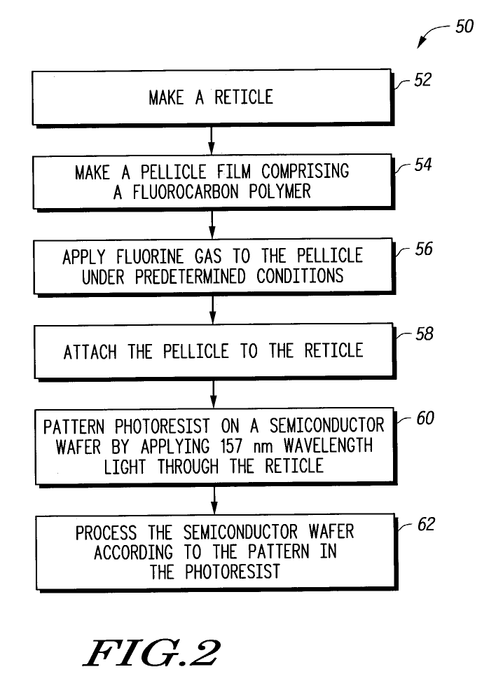

FIG. 2 illustrates, in flow chart form, a method for making a semiconductor device in accordance with the present invention. Referring to both FIG. 1 and FIG. 2, at step 52, a reticle is patterned for exposing the photoresist on a semiconductor wafer. The pattern is used to form predetermined features on the wafer to create electrical components for an integrated circuit.

At step 54, a pellicle film is constructed using a copolymer, such as for example, Teflon® AF. The copolymer is spin coated on a glass plate. However, in other embodiments, the Teflon® AF may be brushed on, sprayed or dipped. The pellicle film is then attached to a pellicle frame. In the illustrated embodiment, the pellicle frame is made from aluminum. In other embodiments, the frame may be constructed from other materials.

At step 56, the pellicle is exposed to a gas containing fluorine under predetermined conditions. In one embodiment, the gas is applied to the pellicle under a pressure of 10-15 pounds per square inch (PSI) greater than atmospheric pressure at a temperature of 40-50 degrees Celsius for two hours. The gas for treating pellicles has a concentration of 30 percent fluorine and 70 percent nitrogen. Applying the fluorine and nitrogen mixture to the pellicle has the effect of replacing the unwanted hydrogen atoms and carboxylic acid moieties in the pellicle to produce a substantially hydrogen-free pellicle. This has been observed to increase the transparency of the pellicle to light having a shorter wavelength.

In another embodiment, the gas for treating pellicles may have a fluorine concentration of between 10 and 100 percent. The reaction temperature may be between 20 and 80 degrees Celsius. The gas may be applied for a time period of from about 2 hours to about 16 hours. Note that the chamber used to apply the gas to the pellicle may first be purged with nitrogen prior to admitting fluorine.

In yet another embodiment, the fluorine gas may be applied in multiple time periods at multiple fluorine concentrations. For example, at a temperature of about 25 degrees Celsius, the fluorine gas may be delivered at a concentration for 10 percent for six hours, followed by treatment of the pellicle with 25 percent fluorine for six hours, followed by treatment with 65 percent fluorine for six hours.

At step 58, pellicle film 28 and frame 26 are attached to reticle 24. Pellicle 28 functions to protect reticle 24 from contamination that would likely interfere with the accurate transmission of the reticle pattern features to the semiconductor wafer 18. Note that in the illustrated embodiment, pellicle film 28 is exposed to the gas before be attached to the reticle. In another embodiment, the pellicle may be exposed to the gas after being attached to the reticle.

At step 60, photoresist on the semiconductor wafer is patterned in optical microlithography system 10 by applying 157 nm wavelength light through reticle 24. At step 62, the semiconductor wafer undergoes further processing to form an integrated circuit.

In the foregoing specification, the invention has been described with reference to specific embodiments. However, one of ordinary skill in the art will appreciate that various modifications and changes can be made without departing from the scope of the present invention as set forth in the claims below. For example, nitrogen is used with fluorine in the illustrated embodiment to change the concentration of the fluorine. However, in other embodiments, another inert gas may be used instead of nitrogen. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variations thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for making a semiconductor device, comprising:
providing a reticle having a pattern;
providing a pellicle substantially comprising a fluorocarbon;
applying a gas comprising fluorine to the pellicle to remove hydrogen from the pellicle;
after applying the gas, attaching the pellicle to the reticle;
providing a semiconductor wafer having a photoresist layer thereon;
exposing the photoresist layer according to the pattern by passing light having a wavelength of less than or equal to 193 nanometers through the mask to the photoresist layer; and
processing the semiconductor wafer according to the pattern to form the semiconductor device.

2. The method of claim 1, wherein the applying the gas to the pellicle also removes carboxylic acid moieties from the pellicle.

3. The method of claim 1, wherein the applying the gas occurs at temperature between 20 and 80 degrees Celsius.

4. The method of claim 3, wherein the applying the gas occurs at a temperature range of about 40 to 50 degrees Celsius.

5. The method of claim 1, wherein the gas has a fluorine concentration between 10 and 100 percent.

6. The method of claim 1, wherein the gas has a fluorine concentration in a range of 10 to 30 percent.

7. The method of claim 1, wherein the applying the gas begins at a first concentration of fluorine and changes to a second concentration of fluorine, wherein the first concentration is lower than the second concentration.

8. The method of claim 1, wherein the gas further comprises nitrogen.

9. The method of claim 1, wherein the applying the gas is for a time in a range of 2 hours to 16 hours.

10. The method of claim 9, wherein the applying the gas is for about 2 hours.

11. The method of claim 1, wherein the applying the gas comprises:
initially flowing substantially pure nitrogen;
flowing the gas at a first fluorine concentration for a first time period;
flowing the gas at a second fluorine concentration for a second time period;
flowing the gas at a third fluorine concentration for a third time period;
wherein the third fluorine concentration is greater than the second fluorine concentration and the second fluorine concentration is greater than the first fluorine concentration.

12. The method of claim 11 wherein the third time period is after the second time period and the second time period is after the first time period.

13. The method of claim 12, wherein the first, second, and third time periods are of substantially equal duration.

14. The method of claim 1, wherein the applying the gas occurs at a pressure above atmospheric pressure.

15. The method of claim 14, wherein the applying the gas occurs within a pressure range of about 10 to 15 pounds per square inch greater than atmospheric pressure.

16. The method of claim 1, wherein:
the gas further comprises an inert gas;
the gas has a fluorine concentration between about 10 and 30 percent; and
the applying the gas occurs within a temperature range of about 40 to 50 degrees Celsius.

17. The method of claim 1, wherein the applying the gas comprising fluorine comprises increasing a fluorine concentration step-wise over a predetermined time period.

18. A method of processing a semiconductor wafer, comprising
providing a reticle having a pattern;
providing a pellicle substantially comprising a fluorocarbon;
applying a gas comprising fluorine and an inert gas to the pellicle to remove hydrogen from the pellicle at a temperature range of about 40 to 50 degrees Celsius and a fluorine concentration range of about 10 to 30 percent;
forming a photoresist layer on the semiconductor wafer;
exposing the photoresist layer according to the pattern by passing light having a wavelength of about 157 nanometers through the pellicle and the reticle to the photoresist layer.

19. The method of claim 18, wherein the applying the gas occurs at a pressure above atmospheric pressure.

20. The method of claim 19, wherein the fluorine increases in concentration during the applying the gas.

21. The method of claim 18, further comprising attaching the pellicle to the reticle after the applying the gas.

22. The method of claim 18, further comprising attaching the pellicle to the reticle before applying the gas.

23. The method of claim 22, wherein the applying of the gas further comprises applying the gas to the reticle.

24. A method of processing a semiconductor wafer, comprising
providing a reticle having a pattern;
providing a pellicle substantially comprising a fluorocarbon;
applying a gas comprising fluorine and an inert gas to the pellicle;
providing the semiconductor wafer having a photoresist layer thereon;
exposing the photoresist layer according to the pattern by passing light through the reticle and the pellicle to the photoresist layer.

25. The method of claim 24, wherein applying a gas comprising fluorine is for removing hydrogen and carboxylic acid moieties from the pellicle.

26. The method of claim 24, wherein:
the gas has a concentration of fluorine in a range of about 10 to 30 percent; and
the applying the gas occurs in a temperature range of about 40 to 50 degrees Celsius.

27. The method of claim 26, wherein the light has a wavelength of about 157 nanometers.

28. The method of claim 27, wherein the applying the gas occurs in a chamber that is purged with nitrogen prior to fluorine being introduced into the chamber.
